(19) United States
(12) Patent Application Publication
(10) Pub. No.: US 2026/0081584 A1
(43) Pub. Date: Mar. 19, 2026

(54) ACOUSTIC WAVE FILTER WITH SPLIT SHUNT RESONATOR FOR MAGNETIC FIELD CANCELLATION

(71) Applicant: Skyworks Solutions, Inc., Irvine, CA (US)

(72) Inventors: Ahmed E. Hassanien, Savoy, IL (US); Nathan George Jess, Ottawa (CA); Scott J. Smith, Hollis, NH (US)

(21) Appl. No.: 19/317,741

(22) Filed: Sep. 3, 2025

Related U.S. Application Data
(60) Provisional application No. 63/695,768, filed on Sep. 17, 2024.
(60) Provisional application No. 63/695,696, filed on Sep. 17, 2024.

(51) Int. Cl. H03H 9/56

(52) U.S. Cl. CPC H03H 9/568

(57) ABSTRACT

Aspects of this disclosure relate to an acoustic wave filter that includes a first shunt acoustic wave resonator and a second shunt acoustic wave resonator configured such that current flowing through the second shunt acoustic wave resonator generates a magnetic field that at least partly cancels a magnetic field generated by current flowing through the first shunt acoustic wave resonator. For example, current flowing through the second shunt acoustic wave resonator can generate a magnetic field in an opposite direction than a magnetic field generated by current flowing through the first shunt acoustic wave resonator. In embodiments, the first shunt acoustic wave resonator can be on an opposite side of a series acoustic wave resonator than the second shunt acoustic wave resonator in physical layout. Related acoustic wave filter dies, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/695,696, filed September 17, 2024 and titled “ACOUSTIC WAVE FILTER WITH SPLIT SHUNT RESONATOR FOR MAGNETIC FIELD CANCELLATION,” and claims the benefit of priority of U. S. Provisional Application No. 63/695,768, filed September 17, 2024 and titled “ACOUSTIC WAVE FILTER WITH SPLIT SHUNT RESONATOR LAYOUT,” the disclosures of each which are hereby incorporated by reference in their entireties and for all purposes.

### BACKGROUND

### TECHNICAL FIELD

The disclosed technology relates to acoustic wave devices. Embodiments of this disclosure relate to filters that include a split shunt acoustic wave resonator.

### Description of Related Technology

Acoustic wave filters can be implemented in radio frequency electronic systems. For instance, filters in a radio frequency front end of a mobile phone can include acoustic wave filters. An acoustic wave filter can be a band pass filter in certain applications. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

Certain performance specifications are becoming more demanding for filters. Accordingly, acoustic wave filters with improved performance are desired.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is an acoustic wave filter with improved isolation. The acoustic wave filter includes a plurality of series acoustic wave resonators and a plurality of shunt acoustic wave resonators. The plurality of shunt acoustic wave resonators includes a first shunt acoustic wave resonator and a second shunt acoustic wave resonator configured such that current flowing through the second shunt acoustic wave resonator generates a magnetic field that at least partly cancels a magnetic field generated by current flowing through the first shunt acoustic wave resonator. The acoustic wave filter is arranged to filter a radio frequency signal.

The first shunt acoustic wave resonator can be in parallel with the second shunt acoustic wave resonator. The first shunt acoustic wave resonator can be in anti-parallel with the second shunt acoustic wave resonator.

The first shunt acoustic wave resonator and the second shunt acoustic wave resonator can be electrically connected to each other at a node between two series acoustic wave resonators of the plurality of series acoustic wave resonators. The first shunt acoustic wave resonator and the second shunt acoustic wave resonator can both be electrically connected to a series acoustic wave resonator of the plurality of series acoustic wave resonators at a same electrode of the series acoustic wave resonator.

The first shunt acoustic wave resonator and the second shunt acoustic wave resonator can be bulk acoustic wave resonators. All acoustic wave resonators of the acoustic wave filter can be bulk acoustic wave resonators.

The first shunt acoustic wave resonator and the second shunt acoustic wave resonator can be positioned on opposite sides of a series acoustic wave resonator of the plurality of series acoustic wave resonators in physical layout. The first shunt acoustic wave resonator and the second shunt acoustic wave resonator can be symmetrically positioned about a series acoustic wave resonator of the plurality of series acoustic wave resonators in physical layout.

The first shunt acoustic wave resonator and the second shunt acoustic wave resonator can be in a same shunt filter stage of the acoustic wave filter. The acoustic wave filter can include a plurality of additional shunt filter stages that each include a pair of shunt acoustic wave resonators configured such that current flowing through the pair of shunt acoustic wave resonators generates magnetic fields that at least partly cancel each other.

The acoustic wave filter can be a band pass filter having a passband. The first shunt acoustic wave resonator and the second shunt acoustic wave resonator can contribute to rejection below the passband in a frequency domain.

The acoustic wave filter can be a ladder filter.

Another aspect of this disclosure is an acoustic wave filter with improved isolation. The acoustic wave filter includes a plurality of series acoustic wave resonators and a plurality of shunt acoustic wave resonators. The plurality of shunt acoustic wave resonators including a first shunt acoustic wave resonator and a second shunt acoustic wave resonator configured such that current flowing through the second shunt acoustic wave resonator generates a magnetic field in an opposite direction than a magnetic field generated by current flowing through the first shunt acoustic wave resonator. The acoustic wave filter is arranged to filter a radio frequency signal.

The first shunt acoustic wave resonator can be in a same filter stage as the second shunt acoustic wave resonator.

The first shunt acoustic wave resonator and the second shunt acoustic wave resonator can be bulk acoustic wave resonators. All acoustic wave resonator of the acoustic wave filter can be bulk acoustic wave resonators.

The first shunt acoustic wave resonator and the second shunt acoustic wave resonator can be positioned on opposite sides of a series acoustic wave resonator of the plurality of series acoustic wave resonators in physical layout. The first shunt acoustic wave resonator and the second shunt acoustic wave resonator can be symmetrically positioned about a series acoustic wave resonator of the plurality of series acoustic wave resonators in physical layout.

The first shunt acoustic wave resonator and the second shunt acoustic wave resonator can be in a shunt filter stage of the acoustic wave filter. The acoustic wave filter can include one or more additional shunt filter stages that each include a pair of shunt acoustic wave resonators configured such that current flowing through the pair of shunt acoustic wave resonators generates magnetic fields that at least partly cancel each other.

The acoustic wave filter can be a band pass filter having a passband. The first shunt acoustic wave resonator and the second shunt acoustic wave resonator can contribute to rejection below the passband in a frequency domain. The acoustic wave filter can be a ladder filter.

Another aspect of this disclosure is an acoustic wave filter with improved isolation. The acoustic wave filter includes a plurality of series acoustic wave resonators including a series acoustic wave resonator; and a plurality of shunt filter stages including a first shunt filter stage. The first shunt filter stage includes a first shunt acoustic wave resonator and a second shunt acoustic wave resonator. The first shunt acoustic wave resonator is positioned on an opposite side of the series acoustic wave resonator than the second shunt acoustic wave resonator in physical layout. The plurality of series acoustic wave resonators and the plurality of shunt filter stages together are arranged to filter a radio frequency signal.

The first shunt acoustic wave resonator can be symmetric with the second shunt acoustic wave resonator about the series acoustic wave resonator.

The first shunt acoustic wave resonator and the second shunt acoustic wave resonator can be bulk acoustic wave resonators. All acoustic wave resonators of the acoustic wave filter can be bulk acoustic wave resonators.

The plurality of shunt filter stages can include a second shunt filter stage that includes a third shunt acoustic wave resonator and a fourth shunt acoustic wave resonator. The third shunt acoustic wave resonator can be positioned on an opposite side of a second series acoustic wave resonator of the plurality of series acoustic wave resonators than the fourth shunt acoustic wave resonator in physical layout.

Each of the plurality of shunt filter stages can include a pair of shunt acoustic wave resonators on opposing sides of a respective series acoustic wave resonator in physical layout.

The acoustic wave filter can be a band pass filter having a passband. The first shunt acoustic wave resonator and the second shunt acoustic wave resonator can contribute to rejection below the passband.

The acoustic wave filter can be a ladder filter.

Another aspect of this disclosure is an acoustic wave filter with improved isolation. The acoustic wave filter includes a plurality of series acoustic wave resonators including a series acoustic wave resonator, and a plurality of shunt acoustic wave resonators. The plurality of shunt acoustic wave resonators includes a first shunt acoustic wave resonator and a second shunt acoustic wave resonator. The first shunt acoustic wave resonator is positioned on an opposite side of the series acoustic wave resonator than the second shunt acoustic wave resonator in physical layout. The first shunt acoustic wave resonator and the second shunt acoustic wave resonator are both electrically connected to a same electrode of the series acoustic wave resonator. The plurality of series acoustic wave resonators and the plurality of shunt acoustic wave resonators are together arranged to filter a radio frequency signal.

The first shunt acoustic wave resonator can be symmetric with the second shunt acoustic wave resonator about the series acoustic wave resonator.

The first shunt acoustic wave resonator and the second shunt acoustic wave resonator can be bulk acoustic wave resonators.

The first shunt acoustic wave resonator and the second shunt acoustic wave resonator can be in parallel with each other. The first shunt acoustic wave resonator and the second shunt acoustic wave resonator can be in anti-parallel with each other.

The plurality of series acoustic wave resonators can also include a second series acoustic wave resonator. The plurality of shunt acoustic wave resonators can also include a third shunt acoustic wave resonator and a fourth shunt acoustic wave resonator that are positioned on opposite sides of the second series acoustic wave resonator in physical layout.

The plurality of shunt acoustic wave resonators can also include a plurality of pairs of shunt acoustic wave resonators, in which each pair of the plurality of pairs includes one shunt acoustic wave resonator on an opposite side of a respective series acoustic wave resonator of the plurality of series acoustic wave resonators than another shunt acoustic wave resonator.

Another aspect of this disclosure is an acoustic wave filter with improved isolation. The acoustic wave filter includes a plurality of series acoustic wave resonators positioned along a signal propagation direction. The acoustic wave filter also includes a plurality of shunt filter stages each including a pair of shunt acoustic wave resonators. The pair of shunt acoustic wave resonators including a first shunt acoustic wave resonator and a second shunt acoustic wave resonator that that are symmetric with each other in physical layout about the signal propagation direction.

All acoustic wave resonators of the acoustic wave filter can be bulk acoustic wave resonators.

Another aspect of this disclosure is a bulk acoustic wave die that includes a plurality of series acoustic wave resonators positioned along a signal propagation direction and a plurality of shunt filter stages. Each of the shunt filter stages include a pair of shunt acoustic wave resonators. The pair of shunt acoustic wave resonators includes a first shunt acoustic wave resonator and a second shunt acoustic wave resonator that that are symmetric with each other in physical layout about the signal propagation direction.

All acoustic wave resonators of the bulk acoustic wave die are bulk acoustic wave resonators.

Another aspect of this disclosure is a multiplexer for filtering radio frequency signals. The multiplexer includes an acoustic wave filter in accordance with any suitable principles and advantages disclosed herein, and a second filter coupled to the acoustic wave filter at a common node.

Another aspect of this disclosure is a radio frequency module that includes acoustic wave filter in accordance with any suitable principles and advantages disclosed herein, radio frequency circuitry, and a package structure enclosing the acoustic wave filter and the radio frequency circuitry.

Another aspect of this disclosure is a radio frequency system that includes an antenna, an acoustic wave filter in accordance with any suitable principles and advantages disclosed herein, and an antenna switch configured to selectively electrically connect the antenna and a signal path that includes the acoustic wave filter.

Another aspect of this disclosure is a wireless communication device that includes a radio frequency front end including an acoustic wave filter in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with an acoustic wave filter in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1 is a schematic diagram of an example acoustic wave filter.

FIG. 2A is a graph of admittance of acoustic wave resonators of the acoustic wave filter of FIG. 1 over frequency. FIG. 2B is a graph of frequency responses for a simulation of a schematic of the acoustic wave filter of FIG. 1 and for a physical layout of the acoustic wave filter of FIG. 1.

FIG. 3 is a schematic diagram of an acoustic wave filter with split shunt acoustic wave resonators according to an embodiment.

FIG. 4 is an example physical layout of the acoustic wave filter of FIG. 3 according to an embodiment.

FIG. 5A is a graph of frequency responses for simulations of a schematic and a physical layout of an acoustic wave filter. FIG. 5B is a graph of frequency response for simulations of a schematic and a physical layout of an acoustic wave filter with split shunt resonators and a symmetric layout according to an embodiment.

FIG. 6A is a graph of frequency responses for simulations of a schematic and a physical layout of an acoustic wave filter. FIG. 6B is a graph of frequency response for simulations of a schematic and a physical layout of an acoustic wave filter with split shunt resonators and a symmetric layout according to an embodiment.

FIG. 7 is a schematic diagram of an acoustic wave filter with split shunt acoustic wave resonators in a subset of shunt filter stages according to an embodiment.

FIG. 8 is a schematic diagram of an acoustic wave filter with split shunt acoustic wave resonators in one filter stage according to an embodiment.

FIG. 9 is a schematic diagram of a shunt acoustic wave resonator split into two shunt acoustic wave resonators in parallel with each other according to an embodiment.

FIG. 10 is a schematic diagram of a shunt acoustic wave resonator split into two shunt acoustic wave resonators in anti-parallel with each other according to an embodiment.

FIGS. 11A, 11B, 11C, and 11D are schematic diagrams of multiplexers that include a filter with one or more split shunt acoustic wave resonators according to an embodiment.

FIGS. 12, 13, and 14 are schematic block diagrams of modules that include a filter with one or more split shunt acoustic wave resonators according to an embodiment.

FIG. 15 is a schematic block diagram of a wireless communication device that includes a filter with one or more split shunt acoustic wave resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

In certain applications, rejection and/or isolation specifications for filters that include acoustic wave resonators, such as bulk acoustic wave (BAW) resonators, are becoming increasingly demanding. In such applications, effects of physical layout can degrade filter performance relative to simulations of schematic designs.

Filter designers can address degraded performance due to physical layout by increasing the spacing between acoustic wave resonators and radio frequency (RF) traces. Such an approach can result in increased die area. Increased die area can increase costs.

Determining the cause of such degradation in performance due to layout effects can be challenging. Certain layout effects impacting performance of an acoustic wave filter can be due to electromagnetic coupling. When currents enter a BAW chip, a magnetic field can be generated that couples to the output of a filter and/or to one or more other RF signal paths and/or ground. Such a magnetic field can reduce isolation and cause deviation from performance of a schematic level design.

In a BAW filter, one or more shunt BAW resonators can be split into two shunt BAW resonators to mitigate effects due to electromagnetic coupling. In some instances, all shunt BAW resonators of a filter can be split into two shunt BAW resonators. Splitting shunt resonators can result in more symmetric physical layout around a signal propagation direction than without such a shunt resonator split. In some instances, the split resonators can be fully symmetric or almost fully symmetric about the signal propagation direction. With the split shunt resonators on opposing sides of a series resonator that is positioned along the signal propagation direction, generated magnetic fields can at least partly cancel each other and lead to better isolation. Shunt resonators disclosed herein can be used in applications with co-existence.

Using split shunt resonators can result in a more efficient die area usage without large spacing between components on the die. Coupling mitigation from physical layout of one or more split shunt resonators can result in improved performance and better isolation/rejections. For example, more stringent rejection specifications can be met with techniques described herein. There can be improved rejection in a deep rejection region below and/or above a passband of a band pass filter that includes split shunt resonators disclosed herein. In certain applications, embodiments disclosed herein can achieve rejection at levels below -75 decibels (dB), -80 dB, or -85 dB in a deep rejection region below a passband. Accordingly split shunt resonators can contribute to rejection below the passband in the frequency domain. Alternatively or additionally, embodiments disclosed herein can achieve rejection at levels below -75 dB, -80 dB, or -85 dB in a deep rejection region above a passband.

FIG. 1 is a schematic diagram of an example acoustic wave filter 10. The acoustic wave filter 10 is a ladder filter. The acoustic wave filter 10 includes series BAW resonators 11, 12, 13, 14, and 15 and shunt BAW resonators 16, 17, 18, and 19. The series BAW resonators 11 and 15 can have an anti-resonant frequency S1, the series BAW resonators 12 and 14 can have an anti-resonant frequency S2, and the series BAW resonator 13 can have an anti-resonant frequency S3. The shunt BAW resonators 16 and 19 can have a resonant frequency P1, the shunt BAW resonators 17 and 18 can have a resonant frequency P2. In some other applications, the BAW resonators of the acoustic wave filter 10 can have different resonant and/or anti-resonant frequencies.

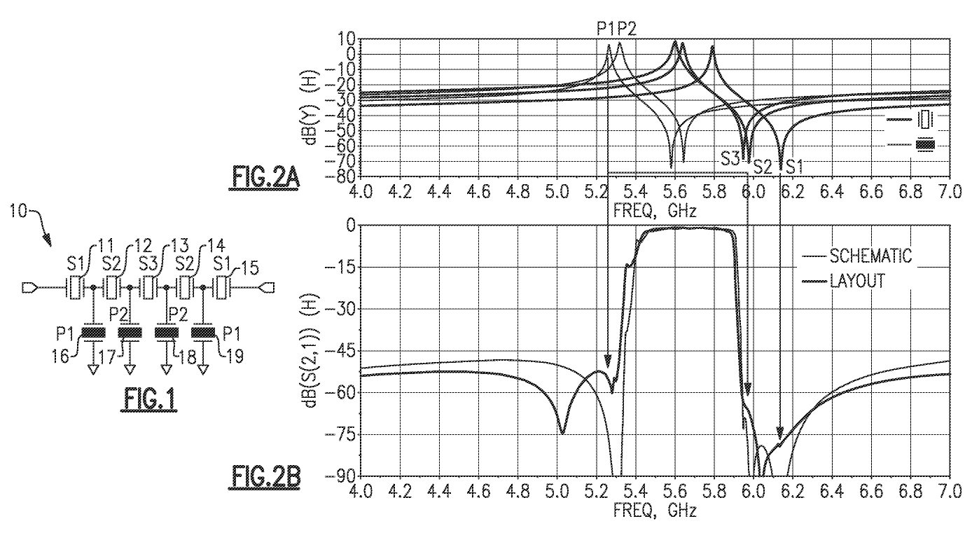

FIG. 2A is a graph of admittance of BAW resonators of the acoustic wave filter 10 of FIG. 1 over frequency. At an anti-resonant frequency fp of a series BAW resonator (open circuit), current can enter a BAW chip and flow out through the shunt BAW resonators to ground. FIG. 2A shows anti-resonant frequencies S1, S2, and S3 for series BAW resonators for an example acoustic wave filter 10 of FIG. 1. At a resonant frequency fs of a shunt BAW resonator (short circuit), current can enter a BAW chip and flow out through the shunt BAW resonators to ground. FIG. 2A shows resonant frequencies P1 and P2 for shunt BAW resonators for an example acoustic wave filter 10 of FIG. 1.

FIG. 2B is a graph of a frequency response for a simulation of a schematic of the acoustic wave filter 10 of FIG. 1 and for a physical layout of the acoustic wave filter 10 of FIG. 1. The acoustic wave filter 10 can be a band pass filter. FIG. 2B shows an example passband for the acoustic wave filter 10. The lower edge of the passband can be created by shunt BAW resonators 16, 17, 18, and 19. The upper edge of the passband can be created by series BAW resonators 11, 12, 13, 14, and 15.

FIG. 2B indicates that schematic level performance deteriorates once layout effects are simulated. At least some of the difference between the performance when layout effects are simulated can be due to a magnetic field generated by current flowing through shunt BAW resonators. The magnetic field can couple to an output of the acoustic wave filter and/or to one or more other RF signal paths. As shown in FIG. 2B, isolation associated with the shunt BAW resonators 16, 17, 18, and 19 is degraded by layout. This can be due to the magnetic field generated by current flowing through the shunt BAW resonators 16, 17, 18, and 19.

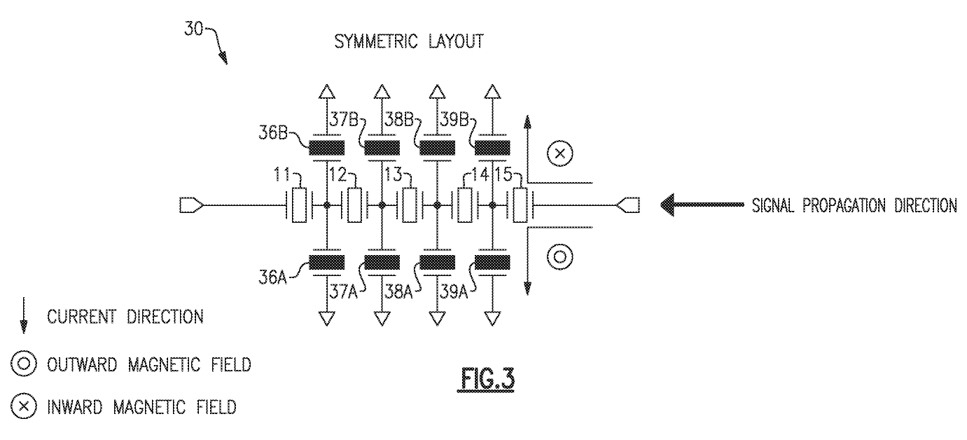

FIG. 3 is a schematic diagram of an acoustic wave filter 30 with split shunt BAW resonators according to an embodiment. The acoustic wave filter 30 is like the acoustic wave filter 10 of FIG. 1, except that shunt resonators are split in the acoustic wave filter 30 and positioned symmetrically about a signal propagation direction in the acoustic wave filter 30 in physical layout. For example, the shunt BAW resonator 16 of the acoustic wave filter 10 is split into the shunt BAW resonators 36A and 36B in the acoustic wave filter 30. Similarly, shunt BAW resonators 17, 18, and 19 of the acoustic wave filter 10 are split int shunt BAW resonators 37A and 37B, 38A and 38B, and 39A and 39B, respectively, in the acoustic wave filter 30. An acoustic wave filter with split shunt BAW resonators can have any suitable number of shunt filter stages and any suitable number of series filter stages.

Splitting shunt resonators as illustrated in the acoustic wave filter 30 can result in a fully symmetric or almost fully symmetric physical layout around the signal propagation direction. Each BAW resonator of a split shunt pair can have approximately half the area relative to an equivalent single BAW resonator. For example, the split BAW resonators 37A and 37B can each have approximately half the area relative to an equivalent single BAW resonator 17 of the acoustic wave filter 10 of FIG. 1.

Magnetic fields generated from current loops in the acoustic wave filter 30 can at least partly cancel each other. As shown in FIG. 3, current flowing through a current loop that includes the shunt BAW resonator 39A can generate a magnetic field in an opposite direction than a magnetic field generated by current flowing through the current loop that includes the shunt BAW resonator 39B. FIG. 3 indicates that current flowing through shunt BAW resonators 36A, 37A, 38A, and 39A generates a magnetic field in a direction out of the page and current flowing through shunt BAW resonators 36B, 37B, 38B, and 39B generates a magnetic field in a direction into the page. Magnetic field cancellation due to split shunt BAW resonators in the acoustic wave filter 30 can result in better isolation for the acoustic wave filter 30 than in the acoustic wave filter 10. Any disclosure related to magnetic fields herein can apply to electromagnetic fields as suitable.

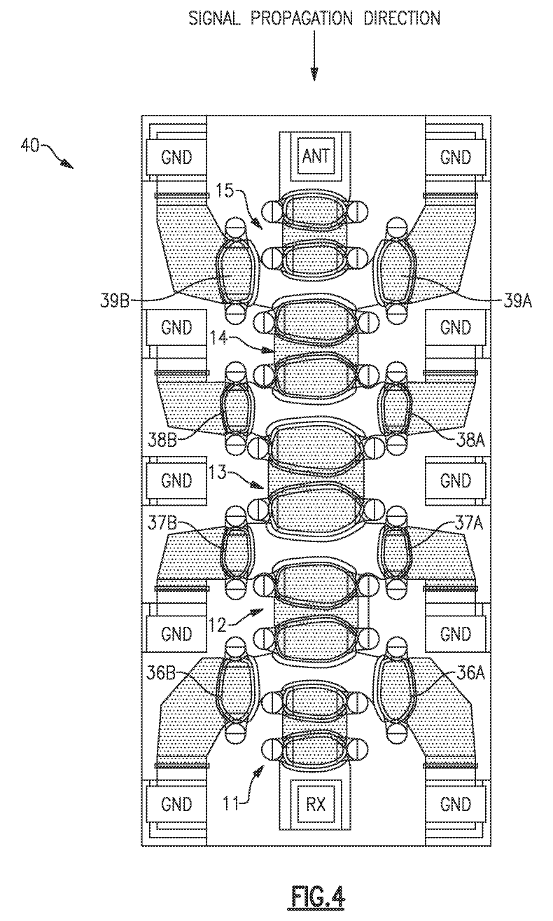

FIG. 4 is an example physical layout 40 of the acoustic wave filter 30 of FIG. 3 according to an embodiment. In the physical layout 40, the BAW resonators are arranged as a ladder filter. As shown in FIG. 4, the physical layout 40 is symmetric about the signal propagation direction along a line that extends from an antenna contact Ant to a receive contact Rx. In certain applications, the physical layout of an acoustic wave filter in accordance with any suitable principles and advantages disclosed herein can be symmetric within a tolerance of being completely symmetric and achieve similar effects. The physical layout of an acoustic wave filter in accordance with any suitable principles and advantages disclosed herein can be symmetric within a tolerance of within 10% of being completely symmetric in certain applications.

The physical layout 40 is for a BAW filter die with a symmetric shunt BAW resonator layout. Each shunt filter stage includes a pair of shunt BAW resonators that are symmetric about the signal propagation direction. The physical layout 40 includes series BAW resonators 11, 12, 13, 14, and 15, a first group of shunt BAW resonators 36A, 37A, 38A, and 39A on one side of the series BAW resonators, and a second group of shunt BAW resonators 36B, 37B, 38B, and 39B on the other side of the of the series BAW resonators. The physical layout of the two groups of the shunt BAW resonators can cancel magnetic fields created by current loops that includes the shunt BAW resonators.

In the physical layout 40, each pair of shunt BAW resonators in a filter stage can be on opposing sides of a series BAW resonator. For example, the pair of shunt BAW resonators 36A and 36B are on opposing sides of the series acoustic BAW resonator 15 in the physical layout 40. Each pair of shunt BAW resonators of a filter stage can be symmetric about a line along the signal propagation direction that extends through a series BAW resonator. Each pair of shunt BAW resonators of a filter stage can be substantially symmetric about a line along the signal propagation direction that extends through a series BAW resonator and achieve magnetic field cancellation disclosed herein.

The shunt BAW resonator 36A can generate a magnetic field in an opposite direction than the shunt BAW resonator 36B in the physical layout. This can provide magnetic field cancellation. When the layout of the shunt BAW resonators 36A and 36B is symmetric, the magnetic field cancellation can be full or nearly full cancellation. In some other applications, magnetic field cancellation can be less than full cancellation. At least partial magnetic field cancellation by split shunt resonators can improve performance in an acoustic wave filter.

In the physical layout 40, each shunt filter stage of the acoustic wave filter 30 includes split shunt BAW resonators. Split shunt BAW resonator resonators of a filter stage can be connected at a node between two series BAW resonators. For example, in FIG. 4, shunt BAW resonators 37A and 37B of a filter stage are connected at a node between series BAW resonator 12 and series BAW resonator 13. The series BAW resonators 12 and 13 are included in different series filter stages. A series BAW resonator of a filter can be split into multiple cascaded BAW resonators in certain applications. For example, as shown in FIG. 4, a series BAW resonator can be split into two cascaded BAW resonators. This can increase one or more of power handling, ruggedness, or suppression of second harmonic power emissions of the series BAW resonator. Split shunt BAW resonator resonators of a filter stage can be electrically connected at a same electrode of a series BAW resonator of the acoustic wave filter 30. For example, in FIG. 4, shunt BAW resonators 378A and 38B are connected at a same electrode of the series BAW resonator 14.

In the physical layout 40, the illustrated resonators are BAW resonators. Each of these BAW resonators can be a film bulk acoustic wave resonator (FBAR) or a BAW solidly mounted resonator (SMR). In certain instances, one of more of the BAW resonators can be a higher order BAW resonator that has an overtone mode as a main mode.

In some other applications, any suitable principles and advantages disclosed herein can be applied to an acoustic wave filter with one or more surface acoustic wave resonators (e.g., one or more temperature compensated surface acoustic wave resonators, one or more multilayer piezoelectric substrate surface acoustic wave resonators, and/or one or more non-temperature compensated surface acoustic wave resonators), one or more laterally excited bulk acoustic wave resonators (XBARs), one or more Lamb wave resonators, one or more boundary acoustic wave resonators, the like, or any suitable combination thereof. Any suitable shunt acoustic wave resonator (e.g., any of the acoustic wave resonators in the preceding sentence) can be split into a pair of shunt acoustic wave resonators arranged in physical layout to provide magnetic field cancellation in accordance with any suitable principles and advantages disclosed herein.

The physical layout 40 is for an receive filter with BAW resonators coupled between an antenna node and a receive node. Any suitable principles and advantages disclosed herein can be applied to a transmit filter.

FIG. 5A is a graph of frequency response for simulations of a schematic design and a physical layout of an acoustic wave filter. The simulated acoustic wave filter corresponds to the acoustic wave filter 10 of FIG. 1 without split shunt resonators. FIG. 5A shows that the schematic simulation has better rejection around 5.3 gigahertz (GHz) than the physical layout simulation. This can be due to layout effects, such as a magnetic field generated by current flowing through shunt BAW resonators. FIG. 5A also shows that the schematic simulation has better rejection slightly below 6 GHz than the physical layout simulation. This can be due to layout effects, such as a magnetic field generated by current flowing through shunt BAW resonators.

FIG. 5B is a graph of frequency responses for simulations of a schematic design and a physical layout of an acoustic wave filter with split shunt resonators having a symmetric layout according to an embodiment. The simulated acoustic wave filter corresponds to the acoustic wave filter 30 of FIG. 3 with the physical layout 40 of FIG. 4. FIG. 5B indicates that the physical layout 40 of FIG. 4 can achieve a frequency response relatively close to the schematic simulation. This can be at least partly due to magnetic field cancellation from split shunt BAW resonators in the physical layout 40. FIG. 5B also includes an improvement in rejection using the physical layout 40 compared to a layout corresponding to the acoustic wave filter 10 of FIG. 1 without split shunt BAW resonators simulated in FIG. 5A. A rejection of below -75 decibels at and around 5.3 GHz is indicated by FIG. 5B. This is an improvement for the layout simulation of FIG. 5B compared to FIG. 5A. A rejection of below -75 decibels slightly below 6 GHz is indicated by FIG. 5B. This is an improvement for the layout simulation of FIG. 5B compared to FIG. 5A.

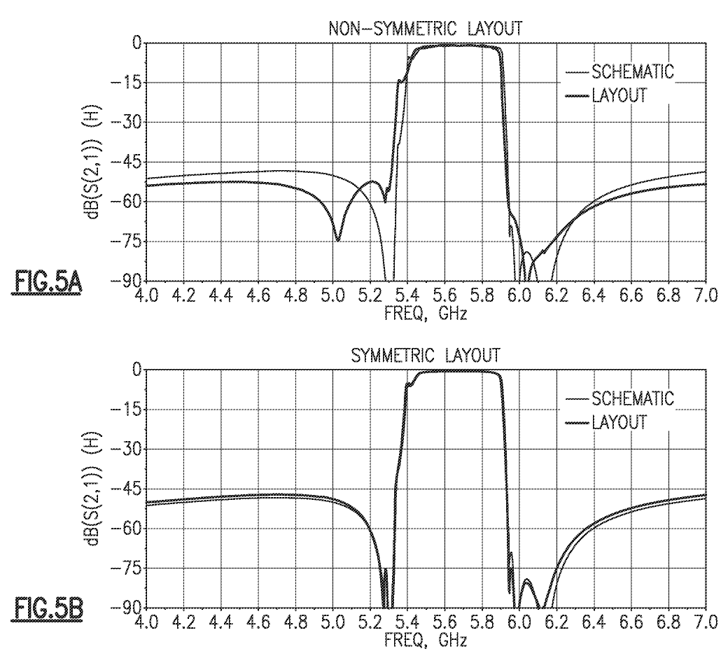

FIG. 6A is a graph of frequency response for simulations of a schematic and a physical layout of an acoustic wave filter. The simulated acoustic wave filter corresponds to the acoustic wave filter 10 of FIG. 1 without split shunt resonators. FIG. 6A shows that the schematic simulation has better rejection below the passband than the physical layout simulation. This can be due to layout effects, such as a magnetic field generated by current flowing through shunt BAW resonators in the physical layout.

FIG. 6B is a graph of frequency responses for simulations of a schematic and a physical layout of an acoustic wave filter with split shunt resonators and a symmetric layout according to an embodiment. The simulated acoustic wave filter corresponds to the acoustic wave filter 30 of FIG. 3 with the physical layout 40 of FIG. 4. FIG. 6B indicates that the physical layout 40 of FIG. 4 can achieve a frequency response relatively close to the schematic simulation. This can be at least partly due to magnetic field cancellation from split shunt BAW resonators in the physical layout 40. FIG. 6B also includes an improvement in rejection using the physical layout 40 compared to a layout corresponding to the acoustic wave filter 10 of FIG. 1 without split shunt BAW resonators that is simulated in FIG. 6A. A rejection of less than -75 dB below the passband throughout a range from around 4.8 GHz to 5 GHz is indicated by FIG. 6B. A rejection of less than -80 dB above the passband throughout a range from around 5.55 GHz to 5.75 GHz is indicated by FIG. 6B.

FIG. 7 is a schematic diagram of an acoustic wave filter 70 with split shunt acoustic wave resonators in a subset of shunt filter stages according to an embodiment. In the acoustic wave filter 70, two shunt filter stages include split shunt BAW resonators. As illustrated, there are two pairs of split shunt BAW resonators 36A, 36B and 39A, 39B in the acoustic wave filter 70. The pairs of split shunt BAW resonators 36A, 36B and 39A, 39B can provide magnetic field cancellation in accordance with any suitable principles and advantages disclosed herein. Any suitable subset of shunt filter stages of an acoustic wave filter can be split into a pair of shunt acoustic wave resonators in accordance with any suitable principles and advantages disclosed herein.

In some instances, improved rejection at and/or around a particular frequency can be desired. The particular frequency can correspond to a deep rejection region below a passband of a band pass filter that includes the split shunt BAW resonators. The particular frequency can be associated with co-existence. The particular frequency can be associated with another RF signal path with coupling to the filter. The shunt BAW resonators associated with the particular frequency (e.g., a particular frequency below a passband of a band pass filter) can be split in accordance with any suitable principles and advantages disclosed herein.

As an example corresponding to FIG. 7, pairs of shunt BAW resonators 36A, 36B and 39A, 39B of the acoustic wave filter 70 having a resonant frequency P1 of FIG. 2A can be split and physically laid out to achieve at least partial magnetic field cancellation. This can improve rejection at and/or around frequency P1.

As another example, a filter can include a shunt BAW resonator with a resonant frequency of 5.8 GHz and a shunt BAW resonator with a resonant frequency of 5.9 GHz. In this example, deeper rejection at 5.9 GHz can be desired. The shunt BAW resonator with a resonant frequency of 5.9 GHz can be split into a pair of generally symmetric BAW resonators to increase rejection at 5.9 GHz for the filter in this example while the shunt BAW resonator with a 5.8 GHz resonant frequency can be implemented with a single BAW resonator in layout.

In certain applications, the shunt BAW resonators 17 and 18 can be positioned on opposing sides of the series BAW resonator 13 in physical layout in the acoustic wave filter 70.

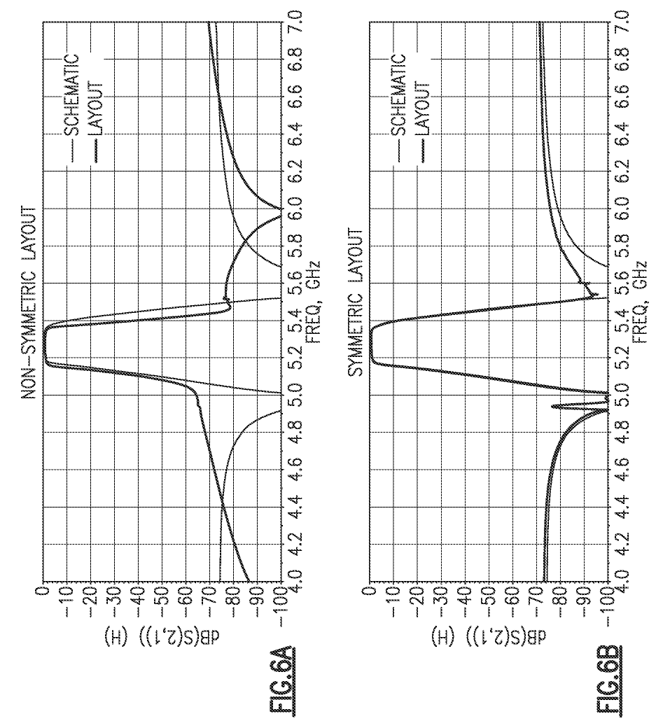

FIG. 8 is a schematic diagram of an acoustic wave filter 80 with split shunt acoustic wave resonators in one filter stage according to an embodiment. In the acoustic wave filter 80, a single shunt filter stage includes split shunt BAW resonators. As illustrated, there is one pair of split shunt BAW resonators 39A, 39B in the acoustic wave filter 80. The pair of shunt BAW resonators 39A and 39B are physically laid out so that current flowing through the shunt BAW resonators 39A and 39B can generate magnetic fields in opposite directions. Any suitable shunt filter stage can include such a pair of split shunt BAW resonators.

FIG. 9 is a schematic diagram of a shunt BAW resonator 90 split into two shunt BAW resonators 92 and 94 in parallel with each other according to an embodiment. In FIG. 9, the thicker line on one side of a BAW resonator can denote a top electrode and a thinner line on the other side of the BAW resonator can denote a bottom electrode. A shunt BAW resonator 90 can be split into two shunt BAW resonators 92 and 94 in parallel with each other in accordance with any suitable principles and advantages disclosed herein. For example, any of the split shunt BAW resonators of FIGS. 3, 4, 7, and/or FIG. 8 can be arranged in parallel with each other. The shunt BAW resonators 92 and 94 can each have approximately half of the area of an equivalent shunt BAW resonator 90.

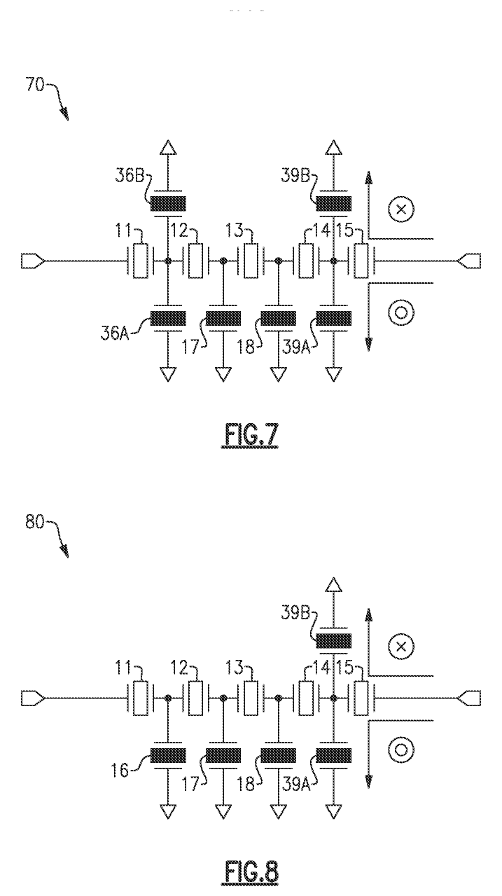

FIG. 10 is a schematic diagram of a shunt BAW resonator 100 split into two shunt BAW resonators 102 and 104 in anti-parallel with each other according to an embodiment. In FIG. 10, the thicker line on one side of a BAW resonator can denote a top electrode and a thinner line on the other side of the BAW resonator can denote a bottom electrode. Anti-parallel BAW resonators are BAW resonators that are connected in parallel with each other with their polarities reversed. A shunt BAW resonator 100 can be split into two shunt BAW resonators 102 and 104 in anti-parallel with each other in accordance with any suitable principles and advantages disclosed herein. For example, the any of the split shunt BAW resonators of FIGS. 3, 4, 7, and/or FIG. 8 can be arranged in anti-parallel with each other. Anti-parallel BAW resonators 102 and 104 can reduce second harmonic power emissions (H2) compared to implementing a single BAW resonator. The shunt BAW resonators 102 and 104 can each have approximately half of the area of an equivalent shunt BAW resonator 100.

BAW devices arranged as disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators in a variety of applications, such as but not limited to electronic timing products. In certain applications, a BAW oscillator can be implemented in a part with another type of oscillator, such as a crystal oscillator. In applications outside of BAW filters, split shunt BAW resonators can be implemented in applications with differential signals, for example.

BAW resonators disclosed herein can be implemented in a variety of filters. Such filters can be arranged to filter a radio frequency signal. BAW resonators disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave resonators disclosed herein can be implemented in filters with one or more other types of resonators and/or with passive impedance elements, such as one or more inductors and/or one or more capacitors. Example filter topologies with split shunt resonators are shown in FIGS. 3, 7, and FIG. 8.

A filter in accordance with any suitable principles and advantages disclosed herein can be arranged to filter a radio frequency signal in a Wi-Fi operating band. The Wi-Fi operating band can be a 5 GHz Wi-Fi operating band in some applications. Such a filter can filter a Wi-Fi signal in a frequency range from 5 GHz to 6 GHz, such as in a range from 5.15 GHz to 5.85 GHz. A filter in accordance with any suitable principles and advantages disclosed herein can be arranged to filter a radio frequency signal having a frequency below 3 GHz. A filter in accordance with any suitable principles and advantages disclosed herein can be arranged to filter a radio frequency signal having a frequency in a range from 6 GHz to 7 GHz. A filter in accordance with any suitable principles and advantages disclosed herein can be arranged to filter a radio frequency in a fifth generation 5G NR operating band within Frequency Range 1 (FR1). FR1 can be from 410 MHz to 7.125 GHz, for example, as specified in a current 5G NR specification. A filter in accordance with any suitable principles and advantages disclosed herein can be arranged to filter a radio frequency signal in a fourth generation (4G) Long Term Evolution (LTE) operating band. A filter in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio – Dual Connectivity (ENDC) application. A multiplexer including any such filters can include one or more other filters with a passband corresponding to a 5G NR operating band and/or a 4G LTE operating band. A filter in accordance with any suitable principles and advantages disclosed herein can be arranged to filter a radio frequency signal in any other suitable operating band, such as a Global Positioning System (GPS) operating band, a Bluetooth operating band, a ZigBee operating band, a WiMax operating band, etc.

The acoustic wave resonators disclosed herein can be advantageous for implementing acoustic wave resonators with relatively high isolation and rejection. This can be advantageous in meeting demanding specifications for acoustic wave filters, such as performance specifications for certain Wi-Fi and/or 5G applications.

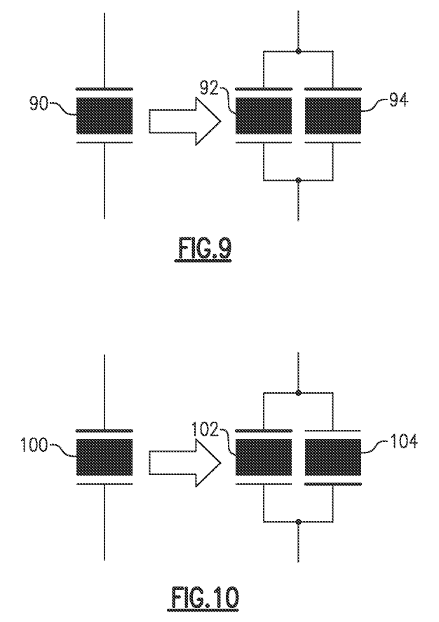

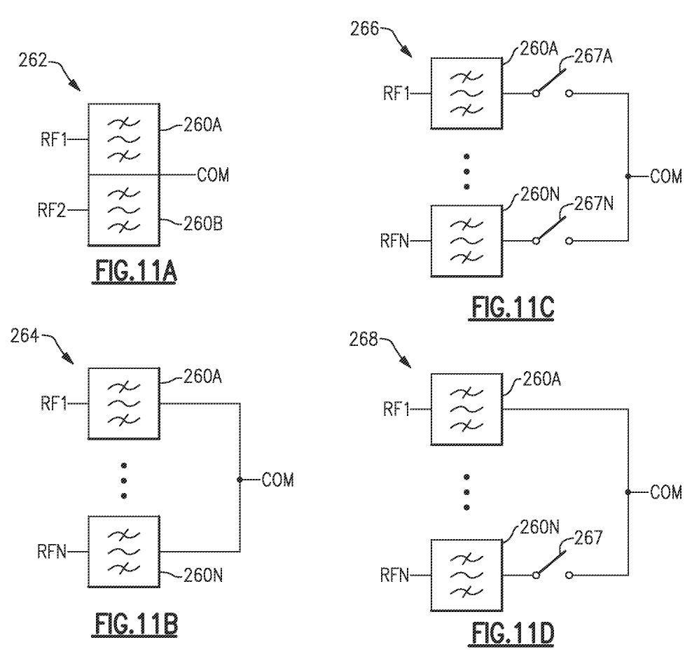

An acoustic wave filter in accordance with any suitable principles and advantages disclosed herein can be implemented as a standalone filter and/or in a filter of any suitable multiplexer. Such filters can be any suitable topology, such as a ladder filter topology. The filter can be a band pass filter arranged to filter a Wi-Fi signal, another wireless local area network signal, a wireless personal area network signal, a 4G LTE signal, and/or a 5G NR signal. Example multiplexers will be discussed with reference to FIGS. 11A to 11D. Any suitable principles and advantages of these multiplexers can be implemented together with each other.

FIG. 11A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A is implemented in accordance with any suitable principles and advantages disclosed herein.

The second filter 260B can be any suitable filter arranged to filter a second radio frequency signal. The second filter 260B can be, for example, an acoustic wave filter, an acoustic wave filter in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. In some instances, an acoustic wave filter can be coupled between a first common node and a second common node, where multiple filters can be coupled to the first common node and multiple filters can be coupled to the second common node. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave filters in accordance with any suitable principles and advantages disclosed herein.

FIG. 11B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A is implemented in accordance with any suitable principles and advantages disclosed herein. The other filter(s) of the multiplexer 264 can include one or more acoustic wave filters, one or more acoustic wave filters that are implemented in accordance with any suitable principles and advantages disclosed herein, one or more LC filters, one or more hybrid acoustic wave LC filters, the like, or any suitable combination thereof.

FIG. 11C is a schematic diagram of a multiplexer 266 that includes an acoustic wave filter according to an embodiment. The multiplexer 266 is like the multiplexer 264 of FIG. 11B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 11D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

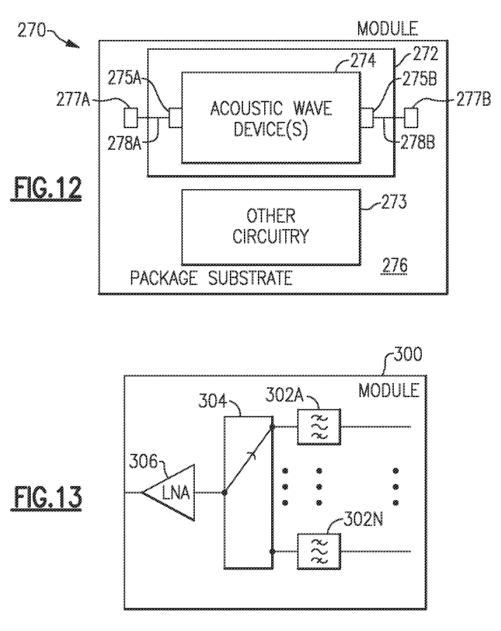

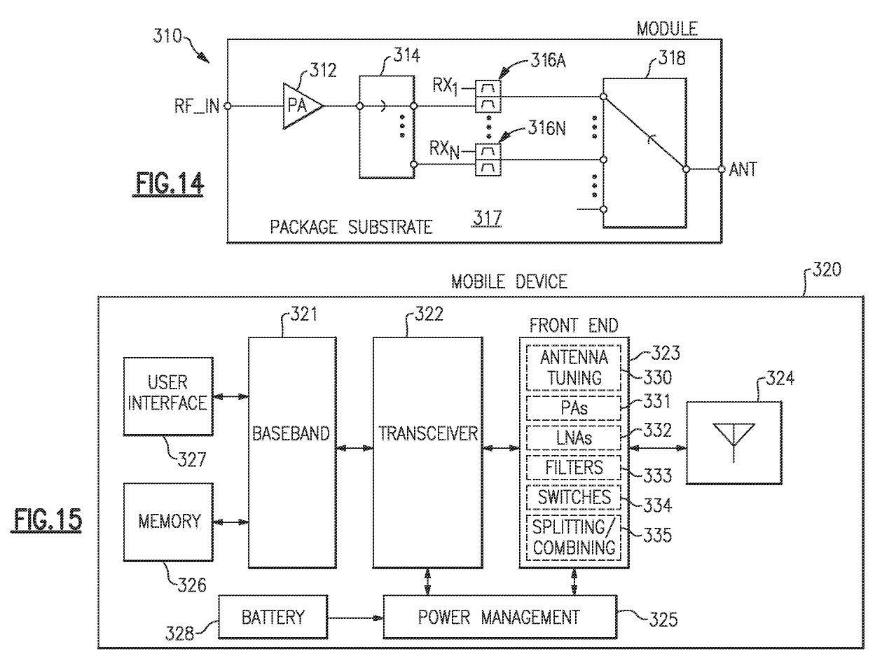

Acoustic wave devices disclosed herein can be implemented in a variety of packaged modules. Some example packaged modules will now be disclosed in which any suitable principles and advantages of the acoustic wave filters disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 12, 14, and FIG. 14 are schematic block diagrams of illustrative packaged modules according to certain embodiments. Any suitable combination of features of these packaged modules can be implemented with each other.

FIG. 12 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW resonators in certain applications.

The acoustic wave component 272 shown in FIG. 12 includes one or more acoustic wave devices 274 and terminals 275A and 275B. The one or more acoustic wave devices 274 include one or more split shunt acoustic wave resonator pairs implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 12. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 13 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 14 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 8 and/or additional elements. The radio frequency module 310 may include any one of the acoustic wave filters in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can be implemented in accordance with any suitable principles and advantages disclosed herein. Similarly, one or more of the receive filters can be implemented in accordance with any suitable principles and advantages disclosed herein. Although FIG. 14 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The acoustic wave filters disclosed herein can be implemented in wireless communication devices. FIG. 15 is a schematic block diagram of a wireless communication device 320 that includes an acoustic wave filter according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 15 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters implemented in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 15, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 15, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An acoustic wave filter with improved isolation, the acoustic wave filter comprising:
a plurality of series acoustic wave resonators; and
a plurality of shunt acoustic wave resonators, the plurality of shunt acoustic wave resonators including a first shunt acoustic wave resonator and a second shunt acoustic wave resonator configured such that current flowing through the second shunt acoustic wave resonator generates a magnetic field that at least partly cancels a magnetic field generated by current flowing through the first shunt acoustic wave resonator, and the acoustic wave filter arranged to filter a radio frequency signal.

2. The acoustic wave filter of claim 1 wherein the first shunt acoustic wave resonator is in parallel with the second shunt acoustic wave resonator.

3. The acoustic wave filter of claim 1 wherein the first shunt acoustic wave resonator is in anti-parallel with the second shunt acoustic wave resonator.

4. The acoustic wave filter of claim 1 wherein the first shunt acoustic wave resonator and the second shunt acoustic wave resonator are electrically connected to each other at a node between two series acoustic wave resonators of the plurality of series acoustic wave resonators.

5. The acoustic wave filter of claim 1 wherein the first shunt acoustic wave resonator and the second shunt acoustic wave resonator are both electrically connected to a series acoustic wave resonator of the plurality of series acoustic wave resonators at a same electrode of the series acoustic wave resonator.

6. The acoustic wave filter of claim 1 wherein the first shunt acoustic wave resonator and the second shunt acoustic wave resonator are bulk acoustic wave resonators.

7. The acoustic wave filter of claim 1 wherein all acoustic wave resonators of the acoustic wave filter are bulk acoustic wave resonators.

8. The acoustic wave filter of claim 1 wherein the first shunt acoustic wave resonator and the second shunt acoustic wave resonator are positioned on opposite sides of a series acoustic wave resonator of the plurality of series acoustic wave resonators in physical layout.

9. The acoustic wave filter of claim 1 wherein the first shunt acoustic wave resonator and the second shunt acoustic wave resonator are symmetrically positioned about a series acoustic wave resonator of the plurality of series acoustic wave resonators in physical layout.

10. The acoustic wave filter of claim 1 wherein the first shunt acoustic wave resonator and the second shunt acoustic wave resonator are in a shunt filter stage of the acoustic wave filter, and the acoustic wave filter includes a plurality of additional shunt filter stages that each include a pair of shunt acoustic wave resonators configured such that current flowing through the pair of shunt acoustic wave resonators generates magnetic fields that at least partly cancel each other.

11. The acoustic wave filter of claim 1 wherein the acoustic wave filter is a band pass filter having a passband, and the first shunt acoustic wave resonator and the second shunt acoustic wave resonator contribute to rejection below the passband in a frequency domain.

12. The acoustic wave filter of claim 1 wherein the acoustic wave filter is a ladder filter.

13. An acoustic wave filter with improved isolation, the acoustic wave filter comprising:
a plurality of series acoustic wave resonators; and
a plurality of shunt acoustic wave resonators, the plurality of shunt acoustic wave resonators including a first shunt acoustic wave resonator and a second shunt acoustic wave resonator configured such that current flowing through the second shunt acoustic wave resonator generates a magnetic field in an opposite direction than a magnetic field generated by current flowing through the first shunt acoustic wave resonator, and the acoustic wave filter arranged to filter a radio frequency signal.

14. The acoustic wave filter of claim 13 wherein the first shunt acoustic wave resonator is in a same filter stage as the second shunt acoustic wave resonator.

15. The acoustic wave filter of claim 13 wherein the first shunt acoustic wave resonator and the second shunt acoustic wave resonator are bulk acoustic wave resonators.

16. The acoustic wave filter of claim 13 wherein the first shunt acoustic wave resonator and the second shunt acoustic wave resonator are positioned on opposite sides of a series acoustic wave resonator of the plurality of series acoustic wave resonators in physical layout.

17. The acoustic wave filter of claim 13 wherein the first shunt acoustic wave resonator and the second shunt acoustic wave resonator are symmetrically positioned about a series acoustic wave resonator of the plurality of series acoustic wave resonators in physical layout.

18. The acoustic wave filter of claim 13 wherein the first shunt acoustic wave resonator and the second shunt acoustic wave resonator are in a shunt filter stage of the acoustic wave filter, and the acoustic wave filter includes one or more additional shunt filter stages that each include a pair of shunt acoustic wave resonators configured such that current flowing through the pair of shunt acoustic wave resonators generates magnetic fields that at least partly cancel each other.

19. The acoustic wave filter of claim 13 wherein the acoustic wave filter is a band pass filter having a passband, and the first shunt acoustic wave resonator and the second shunt acoustic wave resonator contribute to rejection below the passband in a frequency domain.

20. A radio frequency module comprising:
an acoustic wave filter including a plurality of series acoustic wave resonators and a plurality of shunt acoustic wave resonators, the plurality of shunt acoustic wave resonators including a first shunt acoustic wave resonator and a second shunt acoustic wave resonator configured such that current flowing through the second shunt acoustic wave resonator generates a magnetic field that at least partly cancels a magnetic field generated by current flowing through the first shunt acoustic wave resonator;
radio frequency circuitry; and
a package structure enclosing the acoustic wave filter and the radio frequency circuitry.
